(19) United States
(12) Patent Application Publication
(10) Pub. No.: US 2026/0026307 A1
(43) Pub. Date: Jan. 22, 2026

(54) SEMICONDUCTOR DIE RELEASING WITHIN CARRIER WAFER

(71) Applicant: Micron Technology, Inc., Boise, ID (US)

(72) Inventors: Srinivasa Reddy Yeduru, Meridian, ID (US); Farrell M. Good, Meridian, ID (US); Matthew Thorum, Boise, ID (US); Guohua Wei, Boise, ID (US); Gurtej S. Sandhu, Boise, ID (US)

(21) Appl. No.: 19/270,455

(22) Filed: Jul. 15, 2025

Related U.S. Application Data
(60) Provisional application No. 63/672,681, filed on Jul. 17, 2024.

(51) Int. Cl. H01L 21/683; H01L 21/304; H01L 21/78; H01L 23/00; H01L 23/31; H01L 25/065

(52) U.S. Cl. CPC H01L 21/6835; H01L 21/304; H01L 21/78; H01L 23/3121; H01L 24/29; H01L 24/32; H01L 25/0655; H01L 25/0657; H01L 2221/68354; H01L 2221/68381; H01L 2224/29147; H01L 2224/29155; H01L 2224/29166; H01L 2224/32145; H01L 2224/32225; H01L 2225/06541

(57) ABSTRACT

A semiconductor die assembly is introduced in this disclosure. The semiconductor die assembly includes one or more semiconductor dies, a dielectric layer disposed under a bottom surface of the one or more semiconductor dies, and metal fragments or a metal layer disposed under the dielectric layer, wherein metal-OH bonds or metal-O—Si—OH bonds are disposed on a bottom surface of the dielectric layer. Alternatively, the semiconductor die assembly includes one or more semiconductor dies, a metal layer disposed under a bottom surface of the one or more semiconductor dies, and a metal oxidation layer disposed under the dielectric layer, wherein the metal oxidation layer comprises metal-OH bonds or metal-O—Si—OH bonds.

### CROSS-REFERENCE TO RELATED APPLICATION(S)

The present application claims priority to U.S. Provisional Patent Application No. 63/672,681, filed Jul. 17, 2024, the disclosure of which is incorporated herein by reference in its entirety.

### TECHNICAL FIELD

The present disclosure generally relates to semiconductor device assembly, and more particularly relates to releasing a semiconductor die from a carrier wafer through a metal-silicon oxide bonding interface.

### BACKGROUND

Semiconductor packages typically include a semiconductor die (e.g., memory chip, microprocessor chip, imager chip) mounted on a substrate or an interface wafer and encased in a protective covering (e.g., an encapsulating material). The semiconductor die may include functional features, such as memory cells, processor circuits, or imager devices, as well as bond pads electrically connected to the functional features. The process of attaching semiconductor dies on a semiconductor wafer in general refers as chips on wafer (CoW) process, which can increase throughput and reduce difficulties in handling individual semiconductor dies as they continue to shrink in size. Individual semiconductor dies can further be stacked in the semiconductor assemblies.

In advanced semiconductor manufacturing, a carrier wafer is often utilized to provide structural support to semiconductor dies. Particularly, this carrier wafer can be essential when handling very thin or fragile semiconductor dies that could be damaged during the packaging process. For example, the semiconductor dies can be temporarily bonded to the carrier wafer to allow for easier processing through various packaging steps, and later de-bonded or released from the carrier wafer. Various techniques such as laser de-bonding process or plasma debonding process can be adopted for de-bonding semiconductor wafers from the carrier wafer. The choice of de-bonding technique depends on the thermal sensitivity of the dies, the carrier material, and the tolerance for mechanical stress. It requires a balance between effectively releasing the semiconductor die from the carrier wafer and ensuring that the semiconductor die is not damaged in the process. As semiconductor technology advances and dies become thinner and more fragile, the development of innovative de-bonding techniques is desired.

### BRIEF DESCRIPTION OF THE DRAWINGS

FIGS. 1A through 1F illustrate stages of a process for releasing semiconductor dies from a carrier wafer in accordance with various embodiments of the present technology.

FIGS. 2A through 2C illustrate stages of a process for releasing a stack of semiconductor dies from a carrier wafer in accordance with various embodiments of the present technology.

FIGS. 3A through 3E illustrate stages of a process for releasing a stack of semiconductor dies and a logic semiconductor die from a carrier wafer in accordance with various embodiments of the present technology.

FIG. 4 shows a method flow of releasing semiconductor dies from a carrier wafer for semiconductor device assembly in accordance with various embodiments of the present technology.

FIG. 5 is a schematic block diagram of a system that includes a semiconductor device assembly configured in accordance with one or more embodiments of the present technology.

### DETAILED DESCRIPTION

Conventional Back-End-of-Line (BEOL) and device assembly are critical stages in semiconductor device fabrication, where the front-end processes have been completed and the individual semiconductor dies need to be finished and packaged. The general assembly flow includes a device wafer grinding and thin wafer frame attach. For example, as an initial step, a semiconductor device wafer can be thinned down to a desired thickness for high-density packages and thermal management in a final device. After grinding, the thinned semiconductor device wafer can be attached to a wafer frame which provides support to the semiconductor device wafer, allowing it to withstand subsequent processing steps. The general assembly flow also includes a device wafer dicing and die attach processes. For example, individual semiconductor dies can be separated from the semiconductor device wafer through a dicing process, which can be done using a blade, laser, or stealth dicing methods. Each technique has its own advantages and can be chosen based on the requirements of the semiconductor devices. The separated/sliced semiconductor dies are then attached to their respective package substrates. This die attach process can be crucial for the electrical connection between the semiconductor die and the package as well as for heat dissipation management. In subsequent semiconductor device assembly steps, the attached semiconductor die and package substrate can go through wire bonding, flip-chip attachment, encapsulation, and/or any other processes that lead to a final semiconductor device assembly.

While the conventional BEOL process and semiconductor die assembly flow have been well-established, it faces several limitations when dealing with advanced bonding technologies. For example, the use of temporary frame attach materials can limit the effectiveness of multi-wafer stack dicing. In particular, chipping on the wafer edges is a significant concern as it can lead to defects and yield loss. Moreover, carrier wafers, such as silicon with an adhesive layer, are constrained by the temperature sensitivity of the adhesive materials. Most adhesive materials cannot withstand temperatures above 250° C., which can be a limiting factor in subsequent high-temperature processing steps. In addition, using adhesive materials may increase contamination risks during the packaging process. For example, Adhesive materials can lead to contamination issues, such as sticking problems or adhesive residues, which can compromise the integrity of the semiconductor devices. Further, the above described frame attach methods may not be suitable for advanced multi-wafer bonding technologies, which require more precise and cleaner processes. Additionally, the use of frames and tapes can introduce several restrictions during the fabrication process. For example, they may limit the maximum processing temperature, lead to die fly-off after dicing, result in incorrect die pickup, and may not be suitable for plasma processing steps. As semiconductor devices continue to scale, there is a growing need for innovative solutions that can overcome these limitations and support the advancement of semiconductor die bonding and debonding technologies.

To solve the issues and challenges described above, the present technology introduces an innovative semiconductor die release process within a carrier wafer or substrate. Specifically, this semiconductor die release process utilizes a metal-oxide interface formed in a semiconductor wafer to wafer (W2 W) bonding process and a water-assisted debonding process to release semiconductor dies from the carrier wafer. This novel process provides tunable adhesion strength interface between the bonded semiconductor wafer and carrier wafer, offering advantages to conventional chip to wafer bonding, wafer to wafer bonding, and chaplets processes where individual dies can be released on the carrier wafer substrates after dicing. In addition, this semiconductor die releasing process avoids conventional adhesive material based carrier wafer substate bonding and enables high temperature processing on the carrier wafer. As a result, various semiconductor die to die bonding and wafer to wafer bonding with subsequent BEOL processing can be achieved through the invention process. Further advancements in the present technology can be achieved by resolving stacked wafer dicing challenges and chip to wafer bonding issues.

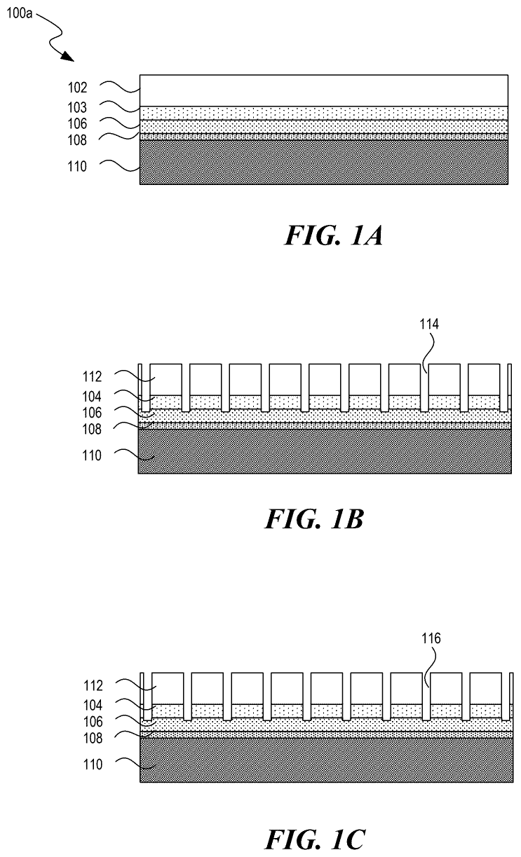

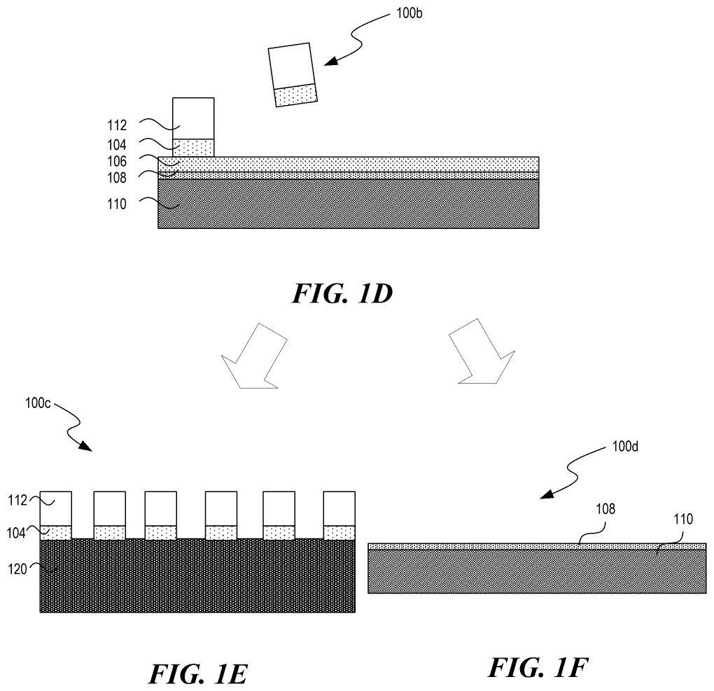

FIGS. 1A through 1F illustrate stages of a process for releasing semiconductor dies from a carrier wafer in accordance with various embodiments of the present technology. For example, FIG. 1A depicts an incoming wafer-to-wafer bonding structure 100a that is integral to the semiconductor die releasing process of the present technology. In this example, a semiconductor device wafer 102 is coated by a silicon oxide layer 103 on its frontside surface. On the semiconductor device wafer 102, integrated circuits can be fabricated on semiconductor substrates using sophisticated manufacturing techniques. These circuits are produced on the semiconductor device wafer 102, which is subsequently divided into individual dies, each representing a distinct semiconductor device. These devices, potentially including memory units, multiprocessor systems, and power semiconductors, can be individually encased and integrated into broader electronic assemblies. With regards to memory devices, various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, non-volatile NAND memory and others. The deposition of the silicon oxide layer 103 can be done by various technologies such as thermal oxidation process, chemical vapor deposition (CVD) process, physical vapor deposition (PVD) process, atomic layer deposition (ALD) process, plating, electroless plating, spin coating, and/or other suitable techniques. In this example, the silicon oxide layer 103 can made of silicon dioxide and has a thickness ranging from 10 nm to 1 μm.

In this example, a buffer layer 108 can be deposited on a frontside surface of a carrier wafer 110. The carrier wafer 110 can be made of materials including silicon, gallium arsenide, silicon carbon, germanium, indium phosphide, gallium nitride, or sapphire. In some other examples, the carrier wafer 100 can be a silicon on insulator (SOI) wafer. In addition, a metal layer 106 can be deposited above the buffer layer 108. Here, the buffer layer 108 serves a dual purpose. Firstly, it acts as a protective barrier for the carrier wafer 110, safeguarding it from potential damage or contamination during downstream processes such as etching, lithography, singulating, or further deposition steps. Secondly, it enhances the adhesion of the metal layer 106 to the carrier wafer 110, which is crucial for the mechanical stability of the metal layer 106 in downstream processes. The choice of buffer layer material is dependent on the specific requirements of the application, including the type of metal layer material being deposited thereon, the processing conditions, and the desired properties of the final semiconductor device. Common materials for buffer layer 108 include silicon dioxide (SiO₂), silicon nitride (Si₃N₄), titanium (Ti), titanium nitride (TiN), and tantalum (Ta), among others. These materials can be selected for their compatibility with silicon, their ability to act as diffusion barriers, and their adhesion-promoting properties. In this example, the buffer layer 108 can be deposited by the CVD process, PVD process, or ALD process. In addition, the buffer layer 108 may have a thickness ranging from 10 nm to 1 μm. Once the buffer layer 108 is in place, the metal layer 106 can be deposited thereon using a metal deposition process such as the CVD process, PVD process, ALD process, sputtering process, electroplating process, or an electron beam evaporation process. In this example, the metal layer 106 can be made of materials including nickel (Ni), copper (Cu), titanium (Ti), and their alloys. In addition, the metal layer 106 has a thickness ranging from 100 nm to 1 μm. In some other materials, the metal layer 106 can be made of metal materials that are bondable to silicon oxide.

In this example, a thermal compression bonding (TCB) process can be applied to bond the semiconductor device wafer 102 with the carrier wafer 110. For example, heat and pressure can be applied to the metal layer 106 and silicon oxide layer 103, respectively from the carrier wafer 110 and semiconductor device wafer 102, to form a metal-silicon oxide interface between the metal layer 106 and silicon oxide layer 103. Under the influence of heat and pressure, the materials of the metal layer 106 and silicon oxide layer 103 undergo a diffusion process at the interface, which results in chemical bonds such as Ni—O—Si bonds. Depending on the bonding process conditions and environment conditions, the bonding energy of the Ni—O—Si bonds at the interface of the metal layer 106 and silicon oxide layer 103 can vary from 300 kcal/mol to 800 kcal/mol.

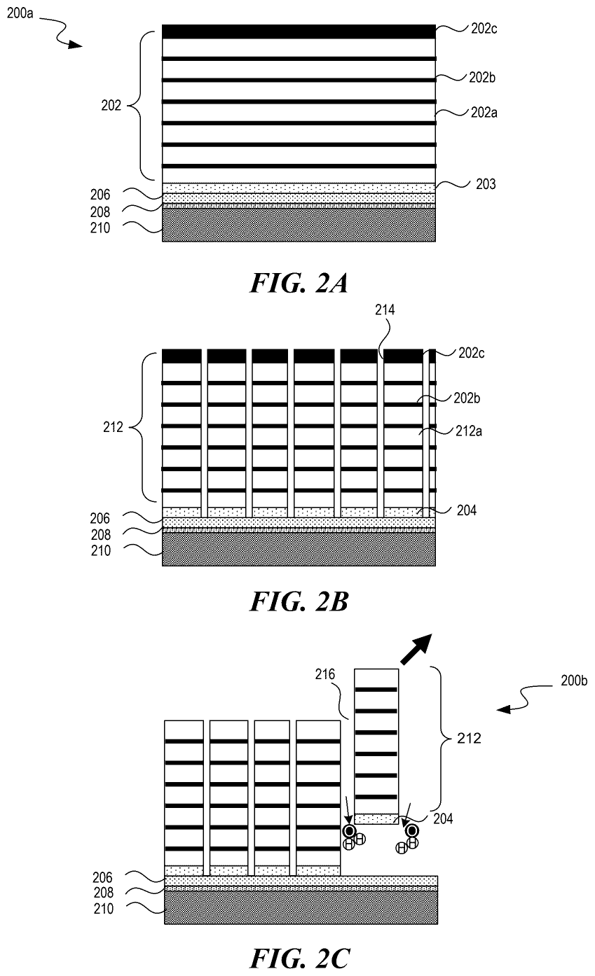

The bonded semiconductor device wafer 102 can be further singulated through plasma dicing or laser dicing processes to form individual semiconductor dies. As shown in FIG. 1B, a plasma dicing process 114 can be adopted to cut or dice the semiconductor device wafer 102 as well as the silicon oxide layer 103 coated thereon into individual die or chips. In comparison to traditional mechanical sawing process, the plasma dicing process 114 offers several advantages, including higher precision, cleaner cuts, and the ability to work with thinner and more fragile materials without causing damages. During the plasma dicing process, the semiconductor device wafer 102 is typically coated with a protective layer, such as photoresist, to shield its circuits and dices during the dicing process. This layer also serves as a mask that defines the dicing lanes where the plasma will cut through. Once the semiconductor device wafer 102 is prepared and the mask is patterned, the wafer-to-wafer bonding structure 100a is placed in a plasma etching chamber. In this chamber, gases such as sulfur hexafluoride (SF₆), Carbon Tetrafluoride (CF₄) or oxygen (O₂) are introduced and ionized to create plasma. The reactive ions and radicals in the plasma selectively etch away the exposed materials along the dicing lanes, effectively cutting the semiconductor device wafer 102 into individual dies. In this example, the plasma dicing process 114 can be tuned to etch selective to the metal layer 106 at the W2 W bonding interface. Here, the selectivity of the plasma etching process can be largely determined by the choice of process gases. Different gases are used to generate plasmas that are selective to different materials. For instance, fluorine-based gases like SF₆ or CF₄ are often used for silicon etching, while chlorine-based gases might be used for etching metals. In addition, the plasma dicing process 114 etch selectivity can also be controlled by adjusting process parameters such as gas flow rates, pressure, power, and temperature. In this example, the above noted parameters can be finely tuned to optimize the etch rate for the target semiconductor device wafer 102 and silicon oxide layer 103 while minimizing the etch rate for the metal layer 106. As shown in FIG. 2B, after the plasma dicing process, the semiconductor device wafer 102 and silicon oxide layer 103 are singulated into individual semiconductor dice 112 and corresponding silicon oxide layers 104 disposed there below. During this process, the carrier wafer 110 and buffer layer 108 are protected by the metal layer 106. After the plasma dicing process 114, the wafer-to-wafer bonding structure 100a could undergo a cleaning process to remove any remaining particles or residues.

As shown in FIGS. 1B and 1C, the plasma dicing process etches out scribe lines between adjacent semiconductor dies 112. The scribe lines extend vertically from the frontside surface of the semiconductor device wafer 102 to the metal layer 106. In a next step shown in FIG. 1C, a water treatment process 116 is conducted to weaken the bonds between the silicon oxide layer 104 and metal layer 106. This process assists in debonding semiconductor dies 112 from the carrier wafer 110 in downstream processes. Here, dihydrogen oxide (H₂O) contained in humid air steam, water condensation, or water can be applied through the scribe lines to the W2 W bonding interface between the silicon oxide layer 104 and metal layer 106. In particular, the dihydrogen oxide can be applied at an elevated temperature ranging from room temperature (RT) to 100° C. To further assist the water treatment process, the carrier wafer 110 can be heated up, e.g., on its backside surface, to an elevated temperature up to 100° C.

The present technology utilizes the water treatment process to enable a subcritical debonding of the semiconductor dies 112 from the carrier wafer 110. Specifically, the water-assisted subcritical debonding refers to interfacial fracture that occurs at the debond driving energy (G) well below the critical adhesion energy (Gc), which results from stress accelerated chemical reactions between environmental species (e.g., H₂O molecules) and strained bonds (e.g., Ni—O—Si bonds) at the W2 W bonding interface. The present technology takes advantage of the environment-assisted subcritical debonding to cleanly releasing the silicon oxide layers 104, together with the semiconductor dies 112 fabricated there on, from the metal layer 106 and the carrier wafer 110.

In this example, exposing the metal-Silicon oxide interface in water significantly reduces the critical adhesion energy at the bonding interface, which is a main reason for an easy and clean debonding of the semiconductor dies 112 from the carrier wafer 110. For example, the effect of water on the critical adhesion energy on the Ni—SiO₂ interface is related to the level of humidity, e.g., a peak Ni—SiO₂ interface potential energy related to the critical adhesion energy decreases in an order of explosion in dry air (e.g., 600-800 kcal/mol), low-moist condition (e.g., 500-600 kcal/mol), and high-moist condition (e.g., 300-300 kcal/mol). This greatly lowered potential energy barrier with moisture introduced in the water treatment process 116 confirms that water can significantly reduce the critical adhesion energy of Ni—SiO₂ interface.

FIG. 1D shows semiconductor dies 100b debonded from the carrier wafer 100. In this example, die debonding processes such as mechanical debonding can be adopted to release individual semiconductor dies 100b through breaking the interface bonding between the silicon oxide layer 104 and metal layer 106. Here, a mechanical force can be applied to separate the semiconductor dies 110b. It can be as simple as using a rubber or plastic wedge to pry the semiconductor dies 110b off the metal layer 106. In some other examples, some other debonding process such as chemical debonding, thermal debonding, and/or UV release debonding can also be applied.

In this example, the dihydrogen oxide introduced to the metal-silicon oxide bonding interface during the water treatment process 116 assists the semiconductor dies 110b debonding process shown in FIG. 1D. In particular, water has a strong polar interaction with strained Si—O—Si crack-tip bonds, causing a break of the hydrogen bond in water and formation of Si—O—H groups at the bonding interface between the silicon oxide layer 104 and metal layer 106. During the debonding process, the applied mechanical stress deforms the metal-O—Si crack-tip bond (e.g., Ni—O—Si bon) that readily reacts with dihydrogen oxide molecules, forming metal-OH bond and Si—OH bond on the carrier wafer 110 side and the semiconductor dies 110b side, respectively. The chemical reaction at the debonding interface can be described as below:

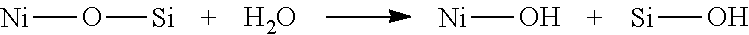

In addition or alternatively, the dihydrogen oxide molecules can access and react with strained Si—O—Si bonds that are located at a secondary atomic layer from a top surface of the silicon oxide layer 104. For example, during the debonding process shown in FIG. 1D, metal-O—Si—OH bond and Si—OH bond can be formed on the carrier wafer 110 side and the semiconductor dies 110b side, respectively.

The water-assisted semiconductor die debonding process can be applied on other metal-Silicon oxide bonding interfaces. For example, Ti can be used to form the metal layer 106 and form a Ti—SiO₂ bonding interface between the silicon oxide layer 104 and metal layer 106. In this example, dihydrogen oxide molecules can be applied during the water treatment process 116 and assist in debonding the semiconductor dies 110b from the carrier wafer 110. During the debonding process, the applied mechanical stress deforms the Ti—O—Si that readily reacts with dihydrogen oxide molecules, forming Ti—OH bond and Si—OH bond on the carrier wafer 110 side and the semiconductor dies 110b side, respectively. In addition or alternatively, the dihydrogen oxide molecules can access and react with strained Si—O—Si bonds that are located at a secondary atomic layer from a top surface of the silicon oxide layer 104. For example, during the debonding process shown in FIG. 1D, Ti—O—Si—OH bond and Si—OH bond can be formed on the carrier wafer 110 side and the semiconductor dies 110b side, respectively.

In another example, Cooper can be used to form the metal layer 106 and form a Cu—SiO₂ bonding interface between the silicon oxide layer 104 and metal layer 106. In this example, dihydrogen oxide molecules can be applied during the water treatment process 116 and assist in debonding the semiconductor dies 110b from the carrier wafer 110. During the debonding process, the applied mechanical stress deforms the Cu—O—Si that readily reacts with dihydrogen oxide molecules, forming Cu—OH bond and Si—OH bond on the carrier wafer 110 side and the semiconductor dies 110b side, respectively. In addition or alternatively, the dihydrogen oxide molecules can access and react with strained Si—O—Si bonds that are located at a secondary atomic layer from a top surface of the silicon oxide layer 104. For example, during the debonding process shown in FIG. 1D, Cu—O—Si—OH bond and Si—OH bond can be formed on the carrier wafer 110 side and the semiconductor dies 110b side, respectively.

During the debonding of semiconductor dies 110b from the carrier wafer 110, metal residues could remain on the debonded semiconductor die, e.g., in a form of metal fragments disposed on the surface of the silicon oxide layer 104. For example, the metal-oxide interface between the metal layer 106 and the silicon oxide layer 104 may be strong, and during the debonding process, some of the metal may not separate cleanly, leaving behind metal fragments or a thin layer of metal on the bottom surface of the silicon oxide layer 104. In addition, the metal-OH bonds and/or metal-O—Si—OH bonds associated with the metal layer 106 during the debonding process can be disposed on the bottom surface of the silicon oxide layer 104 as well. For example, Ni—OH bonds and/or Ni—O—Si—OH bonds may exist on a bottom surface of the debonded semiconductor die 100b. In another example, Ti—OH bonds and/or Ti—O—Si—OH bonds may exist on a bottom surface of the debonded semiconductor die 100b. In some other examples, Cu—OH bonds and/or Cu—O—Si—OH bonds may exist on a bottom surface of the debonded semiconductor die 100b.

In a next step and as shown in FIG. 1E, individual semiconductor die 110b can be bonded on a printed circuit board (PCB) or lead frame 120 to form a semiconductor device assembly 110c. In some example, an epoxy adhesive can be adopted to attach the semiconductor die 110b to the PCB or lead frame 120. For example, the epoxy can be dispensed on the PCB or lead frame 120 and then the semiconductor die 110b can be placed onto it. The semiconductor device assembly 110c can be then cured at elevated temperatures to harden the epoxy adhesive. In some other examples, TCB bonding process or ultrasonic bonding process can be applied to bond the semiconductor die 110b to the PCB or lead frame 120. Finally, the bonded semiconductor die 110b is often encapsulated with a protective material to provide mechanical support and protect against environmental factors.

After the debonding process of FIG. 1D, the carrier wafer 110 can be reused or recycled. Specifically, as shown in FIG. 1F, the carrier wafer 110 and the buffer layer 108 coated thereon can withstand wafer debonding process and then be cleaned and re-prepared for subsequent uses. In some other examples and after the debonding process, residuals can be removed using a wet chemical cleaning process or a CMP process. Further, the carrier wafer 110 can be reused in another semiconductor wafer bonding and semiconductor die debonding process.

In some other examples, the present technology can form similar metal-silicon oxide interface between the semiconductor device wafer 102 and the carrier wafer 110. For example, the metal layer 106 can be deposited on the frontside surface of the semiconductor device wafer 102. The silicon oxide layer 103 can be formed above the carrier wafer 110. The TCB bonding process can be applied on the semiconductor device wafer 102 to bond it with the carrier wafer 110, forming the metal-silicon oxide interface at the W2 W interface. Similar to the metal layer 106 described in FIG. 1A, metal layer deposition processes and metal materials such as Ni, Ti, or Cu can be used to form the metal layer 106 above the semiconductor device wafer 102.

In this example, semiconductor wafer dicing process such as blade dicing can be adopted to cut individual semiconductor dies 112a from the semiconductor device wafer 102. For example, a dicing blade, typically a thin, circular diamond-coated blade, can be used to scribe the semiconductor device wafer 102 along the predetermined dicing streets. The blade rotates at high speeds and is carefully brought down onto the wafer surface to cut through the silicon material. With precise control, the blade dicing process can cut through the semiconductor device wafer 102 as well as the metal layer 106 attached there on. In addition, the blade dicing process can stop on or within the silicon oxide layer coated on the carrier wafer 110. In this example, it is preferrable to have a relative thin thickness of the metal layer 106 (e.g., between 50 nm to 500 nm) and relative thick thickness for the silicon oxide layer 103 (e.g., between 100 nm to 10 μm).

Similar to the water treatment described in FIG. 1C, dihydrogen oxide contained in humid air steam, water condensation, or water can be further applied through the scribe lines to the W2 W bonding interface between the silicon oxide layer 104 and metal layer 106 with elevated temperatures. Here, exposing the metal-silicon oxide interface in water can significantly reduce the critical adhesion energy at the bonding interface, assisting an easy and clean debonding of the semiconductor dies 112 from the carrier wafer 110.

In a downstream process, die debonding processes such as mechanical debonding can be adopted to release individual semiconductor dies 100b through breaking the interface bonding between the silicon oxide layer 104 and metal layer 106, similar to the process described in FIG. 1D. Here, the dihydrogen oxide introduced to the metal-silicon oxide bonding interface during the water treatment process 116 assists the semiconductor dies debonding process. In particular, water has a strong polar interaction with strained Si—O—Si crack-tip bonds, causing a break of the hydrogen bond in water and formation of Si—O—H groups at the bonding interface between the silicon oxide layer 104 and metal layer 106. During this debonding process, the applied mechanical stress deforms the metal-O—Si crack-tip bond, forming metal-OH bond and Si—OH bond on semiconductor dies 110b side and the carrier wafer 110 side, respectively. In addition and alternatively, the dihydrogen oxide molecules can access and react with strained Si—O—Si bonds that are located at a secondary atomic layer from a top surface of the silicon oxide layer 104. The debonded semiconductor dies 110b may also include a metal oxidation layer on its bottom surface. For example, during the debonding process shown in FIG. 1D, metal-O—Si—OH bond and Si—OH bond can be formed on the semiconductor dies 110b side and carrier wafer 110 side, respectively. In this semiconductor die debonding integration scheme, further processes including individual semiconductor die bonding on PCB or lead frame and carrier wafer cleaning & reusable, can be conducted similarly to the ones described in FIGS. 1E and 1F.

The present technology can be applied for stacks of semiconductor dies releasing from a carrier wafer. For example, FIGS. 2A through 2C illustrate stages of a process for releasing a stack of semiconductor dies 202a from a carrier wafer 210 in accordance with various embodiments of the present technology. In this example, the stack 202 of semiconductor dies can be formed above the carrier wafer 210, through a buffer layer 208, a metal layer 206, and a silicon oxide layer 203. Specifically, the buffer layer 208, the metal layer 206, and the silicon oxide layer 203 can be sequentially deposited above the carrier wafer 210. Above the silicon oxide layer 203, the stack 202 of the semiconductor wafers 202a can be bonded on each other through corresponding conductive bonding layer 202b.

In this example, the stack 202 of semiconductor wafers 202a can be 3D stacked DRAM wafers perform as a high bandwidth memory (HBM). It consists of consists of multiple semiconductor wafers 202a that are vertically stacked and interconnected. Each semiconductor wafers 202a in the stack 202 can be a memory wafer (DRAM) or include logic devices such as a central processing unit (CPU) or a graphics processing unit (GPU). Here, the bonding layer 202b is used to adhere each of the stack 202 of the semiconductor wafers 202a, and facilitates the electrical connections in the stack 202. In addition, the stack 202 may also includes a die top protection layer 202c configured to protect the semiconductor wafers 202a disposed under neath. In this example, the die top protection layer 202c can be made of materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Similar to the chemical bonding status described in FIGS. 1A and 1B, there are metal-silicon oxide bonds formed between the metal layer 206 and silicon oxide layer 203. Here, the material composition and film thickness of the buffer layer 208, metal layer 206 and silicon oxide layer 203 can be similar to that of the wafer-to-wafer bonding structure 100a.

As shown in FIG. 2B, a plasma dicing process 214 can be conducted to cut the stack 202 of the semiconductor wafers 202a, generating a stack 212 of semiconductor dies 212a. The working principle of the plasma dicing process 214 here can be similar to the plasma dicing process 114 described in FIG. 1B. This plasma dicing process cuts through the stack 202 of the semiconductor wafers 202a and the silicon oxide layer 204, forming dicing lanes. In addition, the plasma dicing process 214 can be tuned to etch selective to and stop at the metal layer 206. As shown, each of singulated stacks 212 includes multiple vertically bonded semiconductor dies 212a and a silicon oxide layer 204 disposed on the bottom surface of the most bottom semiconductor die.

In a next stacked die debonding process shown in FIG. 2C, the wafer treatment process can be conducted to assist separating the silicon oxide layer 204 from the metal layer 206. As described in FIG. 1C, moisture introduced in the water treatment process can significantly reduce the critical adhesion energy of metal-SiO₂ interface between the stack 212 of semiconductor dies (e.g., the underneath silicon oxide layer 204) and the carrier wafer 210 (e.g., through the metal layer 206). In addition, elevated temperatures can be applied on the carrier wafer 210 or the moisture to assist the wafer treatment process. During this debonding process, the applied mechanical stress deforms the metal-O—Si crack-tip bond at the interface, forming metal-OH bond and Si—OH bond on the carrier wafer 110 side and the semiconductor dies stack 212 side, respectively. In addition and alternatively, the dihydrogen oxide molecules can access and react with strained Si—O—Si bonds that are located at a secondary atomic layer from a top surface of the silicon oxide layer 204. For example, during the debonding process shown in FIG. 2C, Si—OH bond and metal-O—Si—OH bond can be formed on the semiconductor dies stack 212 side and the carrier wafer 210 side, respectively. In this example, the semiconductor dies stack 212 can be easily pulled up due to the low adhesion strength between the silicon oxide layer 204 and the metal layer 206, after the water treatment process 216. Further, the debonded stack of semiconductor dies 212 can be processed in downstream processed, such as bonding with a PCB or lead frame for semiconductor die stack assembly. And the carrier wafer 210 can be reused after certain wafer cleaning process or CMP process.

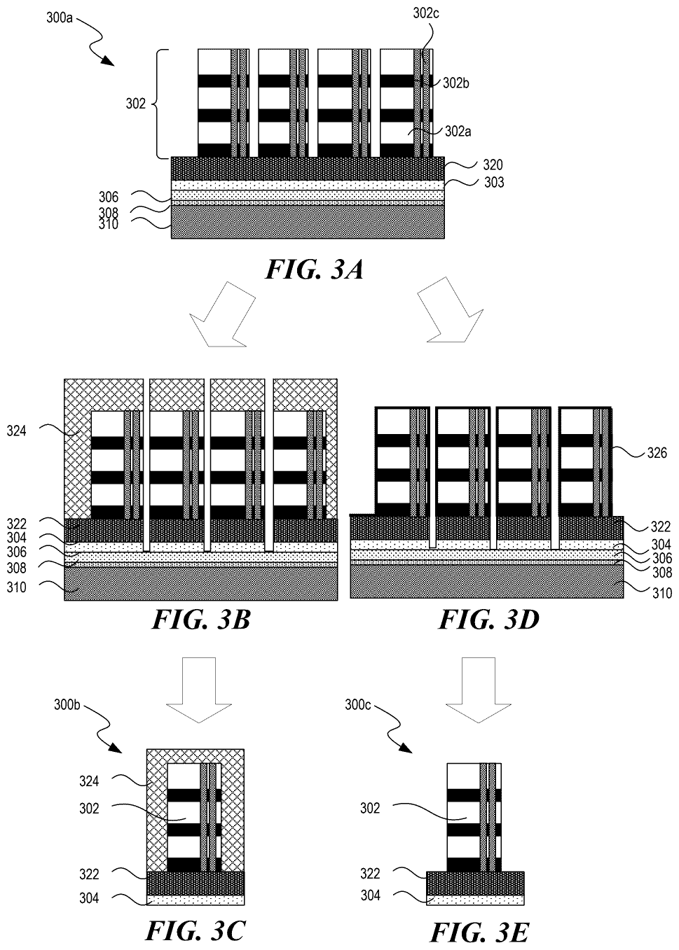

The present technology can also be applied to a chip on wafer bonding/debonding semiconductor device assembly flow. For example, FIGS. 3A through 3E illustrate stages of a process for releasing a stack of semiconductor dies and a logic semiconductor die from a carrier wafer in accordance with various embodiments of the present technology.

The fabrication of individual semiconductor device assembly starts from providing a carrier wafer 310 bonded by a semiconductor wafer 320. The semiconductor wafer 320 can be an interposer (IF) wafer that may include different types of semiconductor dies (e.g., logic dies, controller dies) than the plurality of semiconductor die stacks 302 included in FIG. 3A (e.g., memory dies, DRAM products). The logic dies of the semiconductor wafer 320 can be configured to exchange electrical signals with the semiconductor die stacks 302 bonded thereon and with higher level circuitry (e.g., a host device external to the semiconductor device assembly) coupled with the logic dies. In some embodiments, the semiconductor wafer 320 is an IF wafer and includes interposer dies having various conductive structures (e.g., redistribution layers, vias, interconnects) configured to route electrical signals between the plurality of semiconductor die stacks and higher-level circuitry e.g., a central processing unit (CPU) coupled with the semiconductor die stacks 302 through the interposer die included in the semiconductor wafer 320. In some examples, the semiconductor wafer 320 can be a silicon wafer.

In this example, the semiconductor wafer can be bonded to the carrier wafer 310 through a buffer layer 308 and a silicon oxide layer 304. The buffer layer 308 and silicon oxide layer 304 can be sequentially deposited above the carrier wafer 310. In addition, a TCB bonding process can be utilized to bond the semiconductor wafer 320 with the silicon oxide layer 304. As shown in FIG. 3A, a plurality of semiconductor die stacks 302 can be bonded on the semiconductor wafer 320. In particular, the plurality of semiconductor dies 302a can be stacked through bonding of contact pads, solder balls, or non-conductive filing (NCF) layers 302b disposed there between. In this CoW bonding scheme, the plurality of semiconductor dies 302 can also be bonded using the TCB technique on the front side surface of the semiconductor wafer 320 through the application of heat and pressure there between. Specifically, each one of the semiconductor dies 302a can be a memory core die having a layer of NCF material on its frontside surface. The NCF layer 302b underfills gaps of adjacent semiconductor dies 302a and provides adhesion as well as mechanical support. In some examples, three semiconductor dies 302a can be stacked on the semiconductor wafer 320, targeting a 3H HBM device assembly shown on the end of the flow. The NCF layer 302b may be made of epoxy-based materials such as low viscosity epoxy material, acrylic-based materials, and/or polyimide-based materials. In this example, each of the semiconductor dies 302a can be interconnected through through-silicon-vias (TSV) 302c.

After the CoW bonding process described in FIG. 3A, the semiconductor assembly 300a can be encapsulated by a molding material 324. Here, the molding material 324 can be filled into the gap between adjacent stack 302 of semiconductor dies to form a wafer level molding. As shown, the vertically aligned molding material 324 isolates the stack 302 of semiconductor dies. In some embodiment and after filling the molding material 324, the semiconductor device assembly shown in FIG. 3B may go through a PMC process at an elevated temperature, in which the molding material 324 are cured to have the mold compound fully cross-linked for stiffness. In this example, the molding material 324 can be made of materials including at least one of an epoxy-based liquid compound with granules, an epoxy-based liquid compound without granules, a granular compound, a thin-film based underfill, a thin-film based compound, a resin-based encapsulant, or a polymer. After the molding, the stack 302 of semiconductor dies can be separated, e.g., by a die dicing process. For example, a blade dicing process or a plasma dicing process can be adopted. Specifically, a plasma dicing process can be utilized to cut the molded semiconductor assembly structure. As shown in FIG. 3B, the plasma dicing process can cut through the molding material disposed between adjacent stack 302 of semiconductor dies as well as the semiconductor wafer 320, forming semiconductor dies 322 for corresponding stack 302. The semiconductor dies 322 can be IF dies. The plasma dicing process can further cut through the silicon oxide layer 304 and stop at the metal layer 306 due to its etch selectivity to metal materials.

In a next step, the water treatment process similar to the one described in FIG. 1C can be applied on the semiconductor assembly structure of FIG. 3B. Water can be introduced through the gap between adjacent stacks 302 and access the metal-silicon oxide interface formed between the silicon oxide layer 304 and metal layer 306 to reducing the bonding energy. As shown in FIG. 3C, a mechanical force can be applied to debond/release each of the stacks 302 of semiconductor dies from the carrier wafer 310. FIG. 3C shows the structure of debonded semiconductor die assembly 300b. The semiconductor die assembly 300b is encapsulated by molding material 324 and has semiconductor die 322 and silicon oxide layer 304 disposed there below. In this example, metal residues could remain on the debonded semiconductor die assembly 300b, e.g., on the surface of the silicon oxide layer 304. For example, the metal-oxide interface between the metal layer 306 and the silicon oxide layer 304 may be strong, and during the debonding process, some of the metal may not separate cleanly, leaving behind metal fragments or a thin layer of metal on the bottom surface of the silicon oxide layer 304. In addition, the metal-OH bonds and/or metal-O—Si—OH bonds associated with the metal layer 306 during the debonding process can be disposed on the bottom surface of the silicon oxide layer 304 as well. For example, Ni—OH bonds and/or Ni—O—Si—OH bonds may exist on a bottom surface of the debonded semiconductor die assembly 300b. In another example, Ti—OH bonds and/or Ti—O—Si—OH bonds may exist on a bottom surface of the debonded semiconductor die assembly 300b. In some other examples, Cu—OH bonds and/or Cu—O—Si—OH bonds may exist on a bottom surface of the debonded semiconductor die assembly 300b.

FIGS. 3D and 3E illustrate another flow of semiconductor die stack assembly. In this example, a protective layer 326 can be conformally deposited on a top surface of the CoW bonding structure of FIG. 3A. As shown in FIG. 3D, the protective layer 326 can be disposed on the semiconductor die 322 and on the top surface and side wall surface of bonded semiconductor die stacks 302. In this example, the protective layer 326 can be made of materials including, silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Thin film deposition process such as ALD deposition technique can be adopted to deposit the protective layer 326. After the conformal deposition of protective layer 326, the stack 302 of semiconductor dies can be separated, e.g., by a die dicing process. For example, a blade dicing process or a plasma dicing process can be adopted here. Specifically, a plasma dicing process can be utilized to cut the molded semiconductor assembly structure. As shown in FIG. 3D, the plasma dicing process can cut through the protective layer 326 as well as the semiconductor wafer 320, forming semiconductor dies 322 for corresponding semiconductor die stack 302. The semiconductor dies 322 can be IF dies. The plasma dicing process can further cut through the silicon oxide layer 304 and stop at the metal layer 306 due to its etch selectivity to metal materials.

In a next step, the water treatment process similar to the one described in FIG. 1C can be applied on the semiconductor assembly structure of FIG. 3D. Water can be introduced through the gap between neighboring stacks 302 and access the metal-silicon oxide interface formed between the silicon oxide layer 304 and metal layer 306 to reducing the bonding energy. As shown in FIG. 3E, a mechanical force can be applied to debond/release each of the stacks 302 of semiconductor dies from the carrier wafer 310. FIG. 3E shows the structure of debonded semiconductor die assembly 300c. The semiconductor die assembly 300c can be further processed by a selective wets etching process to remove the protective layer 326. As shown in FIG. 3E, the semiconductor die assembly 300c includes semiconductor die 322 and silicon oxide layer 304 disposed there below. In this example, metal residues could remain on the debonded semiconductor die assembly 300b, e.g., on the surface of the silicon oxide layer 304. For example, the metal-oxide interface between the metal layer 306 and the silicon oxide layer 304 may be strong, and during the debonding process, some of the metal may not separate cleanly, leaving behind metal fragments or a thin layer of metal on the bottom surface of the silicon oxide layer 304. In addition, the metal-OH bonds and/or metal-O—Si—OH bonds associated with the metal layer 306 during the debonding process can be disposed on the bottom surface of the silicon oxide layer 304 as well. For example, Ni—OH bonds and/or Ni—O—Si—OH bonds may exist on a bottom surface of the debonded semiconductor die assembly 300c. In another example, Ti—OH bonds and/or Ti—O—Si—OH bonds may exist on a bottom surface of the debonded semiconductor die assembly 300b. In some other examples, Cu—OH bonds and/or Cu—O—Si—OH bonds may exist on a bottom surface of the debonded semiconductor die assembly 300b.

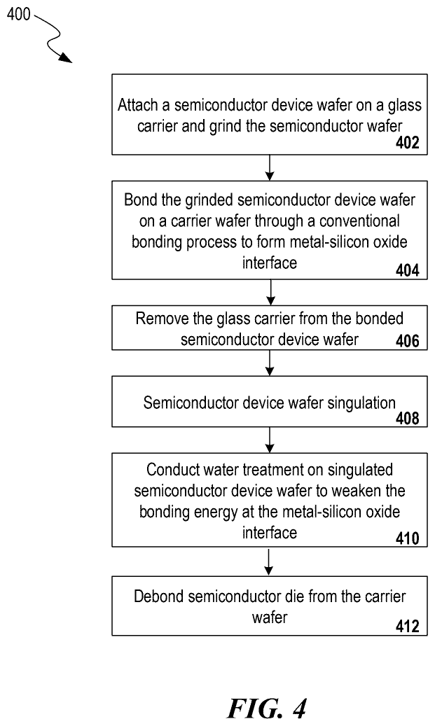

FIG. 4 shows a method 400 of releasing semiconductor dies from a carrier wafer for semiconductor device assembly in accordance with various embodiments of the present technology. For example, the method 400 includes attaching a semiconductor wafer on a glass carrier and grind the semiconductor wafer, at 402. For example, before the W2 W bonding process shown in FIG. 1A, the semiconductor device wafer 102 can be attached on a glass carrier wafer, e.g., using adhesive materials. Specifically, a frontside surface of the semiconductor device wafer 102 can be attached to the glass carrier wafer. Thereafter, a grinding process or CMP process can be applied on the backside surface of the semiconductor device wafer 102 to grind its substrate and reduce the wafer thickness.

The method 400 also includes bonding the grinded semiconductor wafer on a carrier wafer through a bonding process to form a metal-silicon oxide interface, at 404. For example, the grinded semiconductor device wafer 102 can be bonded to the carrier wafer 110 through a TCB bonding process. This W2 W bonding process can form a metal-silicon oxide interface between the silicon oxide layer 103 and metal layer 106, as shown in FIG. 1A.

In addition, the method 400 includes removing the glass carrier from the bonded semiconductor wafer, at 406. For example, the glass carrier used for semiconductor wafer 102 backside grinding can be removed, e.g., through heating a temperature-sensitive adhesive material between the glass carrier and the semiconductor device wafer 102. In some other examples, other carrier wafer removing process such as mechanical separation process can also be utilized.

The method 400 also includes singulating the semiconductor wafer, at 408. For example, the plasma dicing process can be applied on the semiconductor device wafer 102 to form singulated semiconductor dies 112, as shown in FIG. 1B.

Further, the method 400 includes conducting water treatment on singulated semiconductor wafer to weaken the bonding energy at the metal-silicon oxide interface, at 410. For example, the water treatment process 116 can be applied on the singulated semiconductor dies 112, to deliver dihydrogen oxide at an elevated temperature to the metal-silicon oxide interface, as described in FIG. 1C.

Lastly, the method 400 includes debonding semiconductor dies from the carrier wafer, at 412. For example, the dihydrogen oxide delivered at the metal-silicon oxide interface could access and react with strained Si—O—Si bonds at the interface and form metal-O—Si—OH bond and metal-OH bond on the debonded backside surface of the semiconductor dies, as illustrated in FIG. 1D.

The present technology described in this disclosure is particularly well-suited for an array of advanced applications, including bonded wafers, chip-to-wafer integration, and TSV technologies. One of the most compelling features of the present technology is the ability to recycle carrier substrates. This not only presents a cost-effective solution by significantly reducing material expenses but also aligns with sustainable manufacturing practices by minimizing waste. Another advantage of the semiconductor die release process is its capability to enable high-temperature processing. With an operational range extending from 250° C. to an impressive 500° C., it unlocks the potential of chip-to-wafer bonding techniques. This high-temperature threshold is instrumental in achieving superior bond strength and reliability, which are critical in the production of high-performance semiconductor devices. Furthermore, the semiconductor die release process facilitates multi-die bonding to the wafer, which is a significant leap forward in packaging technology. This allows for the BEOL processes to be conducted prior to die attachment, streamlining the manufacturing sequence and enhancing the overall efficiency of the production cycle. Lastly, the present technology boasts an adhesive-free die release mechanism. This innovation eliminates the need for adhesives in the die detachment phase, which not only simplifies the process but also improves the cleanliness and reliability of the final product.

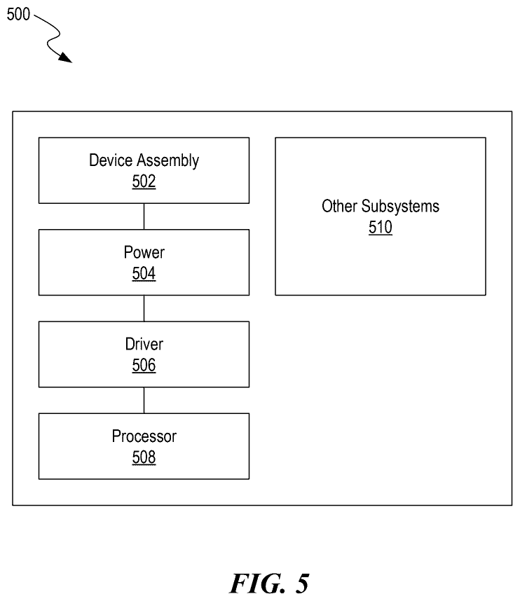

Any one of the semiconductor die assembly technology described above with reference to FIGS. 1 to 4 can be incorporated into any of a myriad of larger and/or more complex systems, a representative example of which is system 500 shown schematically in FIG. 5. The system 500 can include a semiconductor device assembly (e.g., or a discrete semiconductor device) 502, a power source 504, a driver 506, a processor 508, and/or other subsystems or components 510. The semiconductor device assembly 502 can include features generally similar to those of the semiconductor die assembly described above with reference to FIGS. 1 to 4. The resulting system 500 can perform any of a wide variety of functions, such as memory storage, data processing, and/or other suitable functions. Accordingly, representative systems 500 can include, without limitation, hand-held devices (e.g., mobile phones, tablets, digital readers, and digital audio players), computers, vehicles, appliances and other products. Components of the system 500 may be housed in a single unit or distributed over multiple, interconnected units (e.g., through a communications network). The components of the system 500 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor die assembly, comprising:
one or more semiconductor dies;
a dielectric layer disposed under a bottom surface of the one or more semiconductor dies; and
metal fragments or a metal layer disposed under the dielectric layer,
wherein metal-OH bonds or metal-O—Si—OH bonds are disposed on a bottom surface of the dielectric layer.

2. The semiconductor die assembly of claim 1, wherein the dielectric layer comprises silicon oxide.

3. The semiconductor die assembly of claim 1, wherein the dielectric layer has a thickness ranging from 10 nm to 1 μm.

4. The semiconductor die assembly of claim 1, wherein the metal fragments or the metal layer comprises metal materials including nickel (Ni), copper (Cu), titanium (Ti), and their alloys.

5. The semiconductor die assembly of claim 1, wherein the one or more semiconductor dies are vertically stacked and electronically interconnected to each other.

6. The semiconductor die assembly of claim 5, wherein the one or more semiconductor dies are bonded to each other through corresponding conductive bonding layers.

7. The semiconductor die assembly of claim 5, wherein the one or more semiconductor dies are bonded to each other through corresponding non-conductive filling material and through silicon vias (TSVs).

8. The semiconductor die assembly of claim 1, further comprising a molding material that encapsulates the one or more semiconductor dies and the dielectric layer.

9. The semiconductor die assembly of claim 1, further comprising an interposer die disposed under the one or more semiconductor dies and above the dielectric layer, wherein the interposer die comprises logic devices.

10. A semiconductor die assembly, comprising:
one or more semiconductor dies;
a metal layer disposed under a bottom surface of the one or more semiconductor dies; and
a metal oxidation layer disposed under the metal layer,
wherein the metal oxidation layer comprises metal-OH bonds or metal-O—Si—OH bonds.

11. The semiconductor die assembly of claim 10, wherein the metal layer and the metal oxidation layer comprise metal materials including nickel (Ni), copper (Cu), titanium (Ti), and their alloys.

12. The semiconductor die assembly of claim 10, wherein the one or more semiconductor dies are vertically stacked and electronically interconnected to each other.

13. The semiconductor die assembly of claim 10, further comprising a molding material that encapsulates the one or more semiconductor dies, the metal layer, and the metal oxidation layer.

14. The semiconductor die assembly of claim 10, further comprising an interposer die disposed under the one or more semiconductor dies and above the metal layer, wherein the interposer die comprises logic devices.

15. A method of semiconductor device assembly, comprising:
bonding a semiconductor device wafer on a carrier wafer through a bonding process to form a metal-silicon oxide interface;
singulating the semiconductor device wafer;
conducting water treatment on singulated semiconductor device wafer to weaken bonding energy at the metal-silicon oxide interface; and
debonding semiconductor dies from the carrier wafer.

16. The method of claim 15, further comprising attaching the semiconductor device wafer on a glass carrier; grinding on a backside of the semiconductor device wafer; and removing the glass carrier from the bonded semiconductor device wafer.

17. The method of claim 15, further comprising bonding the debonded semiconductor dies on a PCB or a lead frame; and cleaning the debonded carrier wafer for recycle.

18. The method of claim 15, wherein the metal-silicon oxide interface is formed between a metal layer disposed above the carrier wafer and a silicon oxide layer disposed under the semiconductor device wafer; and the bonding process includes a thermal compression bonding (TCB) process.

19. The method of claim 18, wherein debonding the semiconductor dies including breaking metal-silicon oxide bond and generating metal-OH bond or metal-O—Si—OH bond on the metal layer.

20. The method of claim 15, wherein the semiconductor device wafer is singulated by a plasma dicing process, a blade dicing process, a laser dicing process, or a stealth dicing process.
